(19) United States
(12) Patent Application Publication
(10) Pub. No.: US 2013/0026884 A1
(43) Pub. Date: Jan. 31, 2013

(54) ULTRASONIC SENSOR

(71) Applicants: Boum Seock KIM, Gyeonggi-do (KR); Eun Tae PARK, Gyeonggi-do (KR)

(72) Inventors: Boum Seock KIM, Gyeonggi-do (KR); Eun Tae PARK, Gyeonggi-do (KR)

(73) Assignee: SAMSUNG ELECTRO-MECHANICS CO., LTD., Suwon (KR)

(21) Appl. No.: 13/544,362

(22) Filed: Jul. 9, 2012

(30) Foreign Application Priority Data
Jul. 28, 2011 (KR) 10-2011-0075075

(51) Int. Cl. H01L 41/053; H01L 41/113

(52) U.S. Cl. 310/315

(57) ABSTRACT

Disclosed herein is an ultrasonic sensor including: a case including an inner space formed therein; a substrate seated on a bottom surface of the case in the inner space thereof and including a plurality of piezoelectric elements and temperature compensation capacitors mounted in a row therein; and a sound absorbing material mounted on an upper portion of the substrate.

### CROSS REFERENCE(S) TO RELATED APPLICATIONS

This application claims the benefit under 35 U.S.C. Section 119 of Korean Patent Application Serial No. 10-2011-0075075, entitled “Ultrasonic sensor” filed on Jul. 28, 2011, which is hereby incorporated by reference in its entirety into this application.

### BACKGROUND OF THE INVENTION

1. Technical Field

The present invention relates to an ultrasonic sensor, and more particularly, to an ultrasonic sensor capable of being efficiently mass produced by mounting a substrate including a plurality of piezoelectric elements and temperature compensation capacitors coupled thereto on a bottom surface of a case.

2. Description of the Related Art

Generally, two kinds of ultrasonic sensors, that is, a piezoelectricity type ultrasonic sensor and a magnetostriction type ultrasonic sensor have been mainly used as an ultrasonic sensor. The piezoelectricity type ultrasonic sensor uses a phenomenon in which when pressure is applied to an object such as a crystal, a PZT (a piezoelectric material), a piezoelectric polymer, and the like, voltage is generated, and when voltage is applied thereto, vibration is generated. The magnetostriction type ultrasonic sensor uses a Joule effect (a phenomenon in which when a magnetic field is applied, vibration is generated) and a Villari effect (a phenomenon in which when stress is applied, a magnetic field is generated) generated in an alloy of iron, nickel, and cobalt, etc.

An ultrasonic element may be an ultrasonic generator simultaneously with being an ultrasonic sensor. The reason is that the piezoelectricity type ultrasonic sensor senses an ultrasonic wave by voltage generated by applying ultrasonic vibration to a piezoelectric element and generates an ultrasonic wave by vibration generated by applying voltage to the piezoelectric element. In addition, the reason is that the magnetostriction type ultrasonic sensor generates an ultrasonic wave by the Joule effect and senses an ultrasonic wave by the Villari effect .

Currently, a piezoelectricity type ultrasonic sensor using a piezoelectric element has generally been used. The piezoelectricity type ultrasonic sensor has a structure in which the piezoelectric element is seated in an inner portion of a case and an ultrasonic wave generated in the piezoelectric element is discharged to the outside through the case. In the ultrasonic sensor having this structure, since the case serves as an electrode of the piezoelectric element, it is made of a conductive material and is adhered to the piezoelectric element by a conductive adhesive in a state in which it is electrically connected thereto.

Further, in a general ultrasonic sensor, a piezoelectric element is disposed on a bottom surface of a case, and a nonwoven fabric and a substrate are sequentially stacked on an upper portion thereof and then fixed to an inner portion of the case using a molding material, in order to easily discharge ultrasonic vibration of the piezoelectric element to the outside. In this general ultrasonic sensor, since there is no separate fixing unit at the time of assembly of the ultrasonic sensor including the substrate, the nonwoven fabric, and the piezoelectric element, it is difficult to automate the assembly of the ultrasonic sensor and it takes a long time to assemble the ultrasonic sensor.

### SUMMARY OF THE INVENTION

An object of the present invention is to provide an ultrasonic sensor capable of being simply manufactured and mass produced by mounting a substrate including a plurality of piezoelectric elements and temperature compensation capacitors coupled thereto on a bottom surface of a case made of a non-conductive material.

According to an exemplary embodiment of the present invention, there is provided an ultrasonic sensor including: a case including an inner space formed therein; a substrate seated on a bottom surface of the case in the inner space thereof and including a plurality of piezoelectric elements and temperature compensation capacitors mounted in a row therein; and a sound absorbing material mounted on an upper portion of the substrate.

The ultrasonic sensor may further include a plurality of lead wires led from the outside of the case and electrically connected to electrode parts of the substrate through connection lines.

The case may be made of a non-conductive material for insulation from the piezoelectric element inserted into the substrate, and the piezoelectric element mounted in the substrate and coupled to the bottom surface of the case may be closely adhered and coupled to the case through an insulating adhesive.

The ultrasonic sensor may further include a molding material injected and cured into an inner portion of the case to thereby fix the sound absorbing material and the substrate.

The plurality of piezoelectric elements and temperature compensation capacitors inserted into the substrate may have a cubic shape or a rectangular parallelepiped shape, and the plurality of piezoelectric elements may individually vibrate by having power applied thereto through the substrate.

The plurality of piezoelectric elements may vibrate in a direction perpendicular to the bottom surface of the case.

### BRIEF DESCRIPTION OF THE DRAWINGS

FIG. 1 is a perspective view of an ultrasonic sensor according to an exemplary embodiment of the present invention;

FIG. 2 is a cross-sectional view of the ultrasonic sensor according to the exemplary embodiment of the present invention;

FIG. 3 is a plan view of a substrate used in the ultrasonic sensor according to the exemplary embodiment of the present invention; and

FIG. 4 is a cross-sectional view of the substrate used in the ultrasonic sensor according to the exemplary embodiment of the present invention.

### DESCRIPTION OF THE PREFERRED EMBODIMENTS

The acting effects and technical configuration with respect to the objects of an ultrasonic sensor according to the present invention will be clearly understood by the following description in which exemplary embodiments of the present invention are described with reference to the accompanying drawings.

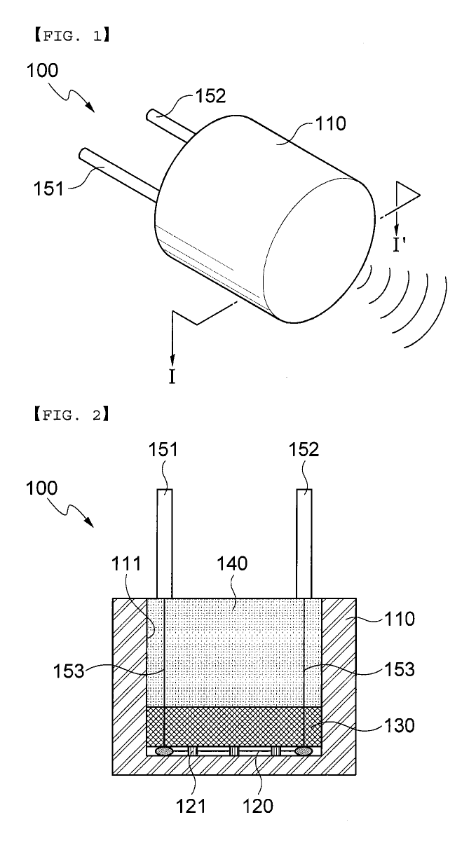

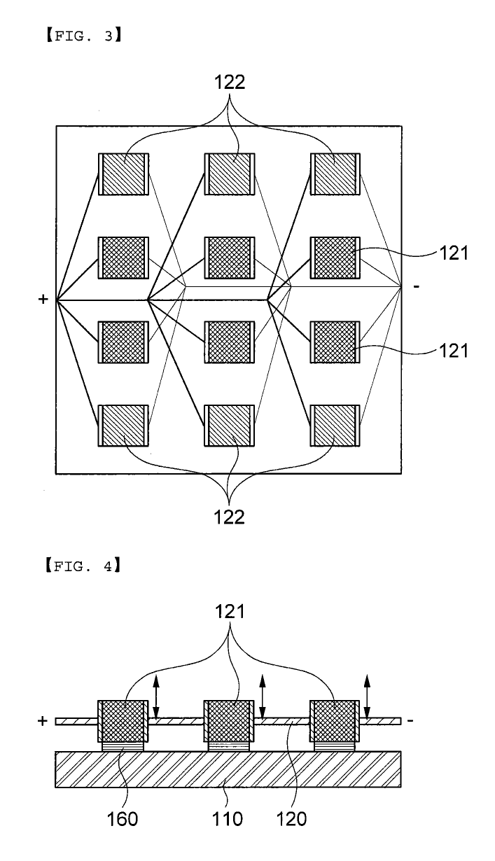

First, FIG. 1 is a perspective view of an ultrasonic sensor according to an exemplary embodiment of the present invention; FIG. 2 is a cross-sectional view of the ultrasonic sensor according to the exemplary embodiment of the present invention; FIG. 3 is a plan view of a substrate used in the ultrasonic sensor according to the exemplary embodiment of the present invention; and FIG. 4 is a cross-sectional view of the substrate used in the ultrasonic sensor according to the exemplary embodiment of the present invention.

As shown, an ultrasonic sensor 100 according to an exemplary embodiment of the present invention may be configured to include a case 110 including an inner space 111 formed therein, a substrate 120 mounted in the case 110, a sound absorbing material 130 coupled to an upper portion of the substrate 120, and a molding material 140 injected into an inner portion of the case 110 so as to be disposed on the sound absorbing material 130.

Here, the substrate 120 may be mounted on a bottom surface of the case 110 in a state in which it includes piezoelectric elements 121 or temperature compensation capacitors 122 mounted in a row or in multiple rows therein.

In addition, the ultrasonic sensor 100 according to the exemplary embodiment of the present invention further includes two lead wires, that is, first and second lead wires 151 and 152, led from the outside of the case 110, wherein the two lead wires 151 and 152 are electrically connected to a power supply or an external device to serve to apply power to the ultrasonic sensor 100, thereby generating vibration in the piezoelectric element 121 and transfer voltage generated by receiving, in the piezoelectric element 121, an ultrasonic wave returned to the piezoelectric element 121 through reflection on an object to be measured in an ultrasonic wave generated in the piezoelectric element 121 to the external device.

The case 110 may have a cylindrical shape or a box shape, and include the inner space 111 capable of receiving a plurality of components in the inner portion thereof.

In addition, the case 110 may be made of a non-conductive material. That is, since the substrate 120 mounted in the case 110 includes circuit patterns and has an anode and a cathode formed at both sides thereof, the piezoelectric element 121 need not be electrically connected to the case 110, which is an applying unit of power for driving the piezoelectric element 121, such that the case 110 may be made of a non-conductive insulating material.

As the substrate 120 mounted on the bottom surface of the case 110, a general printed circuit board (PCB) and a ceramic substrate 120 may be used. In addition, a plurality of through-holes or grooves are formed in the substrate 120, such a plurality of piezoelectric elements 121 and temperature compensation capacitors 122 may be insertedly mounted in a row or in multiple rows in inner portions of the plurality of through-holes or grooves.

The anode (+) and the cathode (−) are implemented at both side terminals (not shown) of the substrate 120. More specifically, since the piezoelectric elements 121 and the temperature compensation capacitors 122 are inserted into the through-holes and the grooves in a state in which they are electrically connected to the circuit patterns formed on the substrate 120, the anode and the cathode may be formed at both sides of the substrate 120.

Here, each of connection lines 153 extended from the first and second lead wires 151 and 152 is electrically connected to the anode and cathode formed at the substrate 120.

The piezoelectric element 121 and the temperature compensation capacitor 122 coupled to the substrate 120 may mainly have a cubic shape or a rectangular parallelepiped shape. In addition, the piezoelectric element 121 is coupled to the substrate 120 in a form in which it penetrates through the substrate 120, such that a lower surface of the piezoelectric element 121 is closely adhered to the bottom surface of the case 110 at the time of mounting of the substrate 120 in the case 110, thereby making it possible to allow the ultrasonic wave to be easily radiated by vibration of the piezoelectric element 121.

The piezoelectric element 121, which is a component generating a vibration ultrasonic wave by displacement generated when current is applied thereto through the substrate 120 to which the first and second lead wires 151 and 152 are electrically connected, is extended or contracted according to polarity of the current applied thereto through the substrate 120. Therefore, when the polarity of the current applied to the piezoelectric element 121 is repeatedly changed, the piezoelectric element 121 vibrates while being repeatedly extended and contracted. The ultrasonic wave may be generated from the piezoelectric element 121 through this principle

The piezoelectric elements 121 may be mounted in the through-holes of the substrate 120 so that they individually vibrate within each of the through-holes and vibrate in a direction (See FIG. 4) perpendicular to the bottom surface of the case 110.

The reason why the piezoelectric elements 121 vibrate in the direction perpendicular to the bottom surface of the case 110 is that when individual piezoelectric elements 121 vibrate, vibration force of the piezoelectric elements 121 may be further increased, by about 3 times, in the case in which the piezoelectric elements 121 vibrate in the direction perpendicular to the bottom surface of the case 110 than in the case in which the piezoelectric elements 121 vibrate in a direction in parallel with the bottom surface of the case 110.

The piezoelectric elements 121 and the temperature compensation capacitors 122 coupled to the substrate 120 are not limited to being disposed at specific positions. However, since the plurality of piezoelectric elements 121 resonate while being individually vibrated, the piezoelectric elements 121 may be densely disposed at a central portion of the substrate 120 and the temperature compensation capacitors 122 may be disposed at outer side portions thereof so that vibration force may doubly increase.

In addition, the piezoelectric elements 121 closely adhered to the bottom surface of the case 110 may be bonded to the case 110 through a non-conductive adhesive 160 made of epoxy, or the like, in order to improve insulation performance and improve bonding density with the case 110.

The reason why the piezoelectric elements 121 are bonded to the case 110 by the non-conductive adhesive made of epoxy is that the non-conductive adhesive made of epoxy does not contain a filler, or the like for conduction, such that it may be applied between the case 110 and the piezoelectric elements 121 in a relatively thin state, and vibration force of the piezoelectric elements 121 may be easily discharged through the case 110 without being cancelled by the thinly applied adhesive.

The sound absorbing material 130 generally made of a nonwoven fabric is disposed on the upper portion of the substrate 120. The sound absorbing material 130 is closely adhered to an upper portion of the piezoelectric elements 121 coupled to the substrate 120 while penetrating therethrough to thereby serve to reduce reverberation which appears after the ultrasonic wave is generated in the piezoelectric element 121.

The reason why the reverberation of the piezoelectric element 121 is reduced through the sound absorbing material 130 is as follows: since the piezoelectric element 121 serves to sense an ultrasonic wave returned to the piezoelectric element through reflection on an object to be measured in an ultrasonic wave radiated to the outside as well as serves to generate an ultrasonic wave, the reverberation which appears after the ultrasonic wave is generated need be completely removed in order to easily sense the reflected ultrasonic and reduce a sensing time.

Meanwhile, the piezoelectric element 121 closely adhered and coupled to the bottom surface of the case 110 through the adhesive 160 has a capacitance value that may be changed according to an external temperature. Due to this change in the capacitance value, reverberation vibration of the piezoelectric element 121 increases at a low temperature (−40° C. or less), such that a malfunction of a system may be generated, and sensitivity of the piezoelectric element 121 is deteriorated at a high temperature (80° C. or more), such that a sensing distance may be reduced.

In order to prevent defect from being generated in the piezoelectric element 121 according to the change in an external temperature as described above, the temperature compensation capacitor 122 is mounted to thereby compensate for the changed capacitance value of the piezoelectric element 121. The temperature compensation capacitors 122 formed at the outer side portions so as to have the same shapes as or similar shapes as those of the piezoelectric elements 121 may be coupled to the substrate 120 while being inserted thereinto or penetrating therethrough.

As described above, the substrate 120 having the piezoelectric elements 121 and the temperature compensation capacitors 122 mounted therein is inserted into the case 110 to as to be disposed at a lower portion of the case 110, the sound absorbing material 130 is coupled to the upper portion of the substrate 120, such that a plurality of components are fixed, and the molding material 140 is then injected and cured into the case 110 so as to be disposed on the upper portion of the sound absorbing material 130, thereby making it possible complete the manufacturing of the ultrasonic sensor 100. Here, the molding material 140 serves to fix and protect the plurality of components positioned in the inner portion of the case 110.

As described above, with the ultrasonic sensor according to the exemplary embodiment of the present invention, when the plurality of piezoelectric elements are mounted in the inner portion of the case, they are mounted in a structure in which they are inserted in a row into the substrate, such that the piezoelectric elements may be easily assembled in the case. Therefore, an assembling process of the ultrasonic sensor becomes simple, thereby making it possible to significantly improve assembling efficiency of the ultrasonic sensor.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

What is claimed is:

1. An ultrasonic sensor comprising:
a case including an inner space formed therein;
a substrate seated on a bottom surface of the case in the inner space thereof and including a plurality of piezoelectric elements and temperature compensation capacitors mounted in a row therein; and
a sound absorbing material mounted on an upper portion of the substrate.

2. The ultrasonic sensor according to claim 1, further comprising a plurality of lead wires led from the outside of the case and electrically connected to an anode and a cathode of the substrate through connection lines.

3. The ultrasonic sensor according to claim 1, wherein the case is made of a non-conductive material.

4. The ultrasonic sensor according to claim 1, wherein the piezoelectric element is closely adhered and coupled to the case through an insulating adhesive.

5. The ultrasonic sensor according to claim 1, further comprising a molding material injected and cured into an inner portion of the case to thereby fix the sound absorbing material and the substrate.

6. The ultrasonic sensor according to claim 1, wherein the piezoelectric elements individually vibrate by having power applied thereto through the substrate and vibrate in a direction perpendicular to the bottom surface of the case.

7. The ultrasonic sensor according to claim 1, wherein the plurality of piezoelectric elements are densely disposed at a central portion of the substrate, and the plurality of temperature compensation capacitors are disposed at outer side portions thereof.
